(19) United States
(12) Patent Application Publication
(10) Pub. No.: US 2024/0290644 A1
(43) Pub. Date: Aug. 29, 2024

(54) TWO LEVEL VACUUM WAFER TRANSFER SYSTEM WITH ROBOTS ON EACH LEVEL

(71) Applicant: Applied Materials, Inc., Santa Clara, CA (US)

(72) Inventors: Dmitry Lubomirsky, Cupertino, CA (US); Kaushik Alayavalli, Sunnyvale, CA (US); Manish Hemkar, Sunnyvale, CA (US); Jeffrey C. Hudgens, San Francisco, CA (US); Maureen Breiling, Campbell, CA (US)

(73) Assignee: Applied Materials, Inc., Santa Clara, CA (US)

(21) Appl. No.: 18/175,344

(22) Filed: Feb. 27, 2023

(51) Int. Cl. H01L 21/677; H01L 21/67

(52) U.S. Cl. CPC H01L 21/67742; H01L 21/67126; H01L 21/67167; H01L 21/67184; H01L 21/6719; H01L 21/67196; H01L 21/67201

(57) ABSTRACT

Exemplary semiconductor processing systems may include a first processing chamber and a second processing chamber. Each processing chamber may define a processing region and a transfer region having a slit valve. Each processing chamber may include a substrate support that is vertically translatable between the processing region and the transfer region. Each processing chamber may include a gas delivery assembly disposed above and in alignment with the substrate support. The first processing chamber and the second processing chamber may be at least substantially aligned along a first vertical axis. The systems may include a first transfer chamber coupled with the first processing chamber via the slit valve. The systems may include a second transfer chamber coupled with the second processing chamber via the slit valve. A transfer robot may be disposed within each transfer chamber. The transfer chambers may be at least substantially aligned along a second vertical axis.

### TECHNICAL FIELD

The present technology relates to semiconductor processes and equipment. More specifically, the present technology relates to substrate processing systems and components.

### BACKGROUND

Semiconductor processing systems often utilize cluster tools to integrate a number of process chambers together. This configuration may facilitate the performance of several sequential processing operations without removing the substrate from a controlled processing environment, or it may allow a similar process to be performed on multiple substrates at once in the varying chambers. These chambers may include, for example, degas chambers, pretreatment chambers, transfer chambers, chemical vapor deposition chambers, physical vapor deposition chambers, etch chambers, metrology chambers, and other chambers. The combination of chambers in a cluster tool, as well as the operating conditions and parameters under which these chambers are run, are selected to fabricate specific structures using particular process recipes and process flows.

Cluster tools often process a number of substrates by continuously passing substrates through a series of chambers and process operations. The process recipes and sequences will typically be programmed into a microprocessor controller that will direct, control, and monitor the processing of each substrate through the cluster tool. Once an entire cassette of wafers has been successfully processed through the cluster tool, the cassette may be passed to yet another cluster tool or stand-alone tool, such as a chemical mechanical polisher, for further processing.

Robots are typically used to transfer the wafers through the various processing and holding chambers. The amount of time required for each process and handling operation has a direct impact on the throughput of substrates per unit of time. Substrate throughput in a cluster tool may be directly related to the speed of the substrate handling robot positioned in a transfer chamber. As processing chamber configurations are further developed, conventional wafer transfer systems may be inadequate. Additionally, as cluster tools scale, component configurations may no longer adequately support processing or maintenance operations.

Thus, there is a need for improved systems and methods that can be used to efficiently direct substrates within cluster tool environments. These and other needs are addressed by the present technology.

### SUMMARY

Exemplary semiconductor processing systems may include a first processing chamber defining a first processing region and a first transfer region having a first slit valve. The first processing chamber may include a first substrate support that is vertically translatable between the first processing region and the first transfer region. The first processing chamber may include a first gas delivery assembly disposed above and in alignment with the first substrate support. The systems may include a first transfer chamber coupled with the first processing chamber via the first slit valve. The systems may include a first transfer robot disposed within the first transfer chamber. The systems may include a second processing chamber defining a second processing region and a second transfer region having a second slit valve. The first processing chamber and the second processing chamber may be at least substantially aligned along a first vertical axis. The second processing chamber may include a second substrate support that is vertically translatable between the second processing region and the second transfer region. The second processing chamber may include a second gas delivery assembly disposed above and in alignment with the second substrate support. The systems may include a second transfer chamber coupled with the second processing chamber via the second slit valve. The systems may include a second transfer robot disposed within the second transfer chamber. The first transfer chamber and the second transfer chamber may be at least substantially aligned along a second vertical axis.

In some embodiments, the first transfer robot may include a first motor assembly and a first end effector assembly. The second transfer robot may include a second motor assembly and a second end effector assembly. The first motor assembly and the second motor assembly may be inverted relative to one another and may be each positioned on an outer-facing side of a respective one of the first transfer chamber and the second transfer chamber. The first end effector assembly and the second end effector assembly may be oriented in a same direction. The first transfer robot may include a first motor assembly and a first end effector assembly. The second transfer robot may include a second motor assembly and a second end effector assembly. The first motor assembly and the second motor assembly may be oriented in a same direction, and may be each positioned on a lower end of a respective one of the first transfer chamber and the second transfer chamber. The first end effector assembly and the second end effector assembly may be oriented in a same direction. The first substrate support and the second substrate support may be operable both independently and concurrently with one another. The first transfer chamber and the second transfer chamber may be fluidly isolated from one another. The systems may include a first load lock that is at least substantially aligned with the first processing chamber along a first horizontal axis. The systems may include a second load lock that is at least substantially aligned with the second processing chamber along a second horizontal axis. The systems may include a factory interface coupled with each of the first load lock and the second load lock.

Some embodiments of the present technology may encompass semiconductor processing systems that may include a first processing chamber defining a first processing region and a first transfer region. The first processing chamber may include a first substrate support that is vertically translatable between the first processing region and the first transfer region. The first processing chamber may include a first gas delivery assembly disposed above and in alignment with the first substrate support. The systems may include a second processing chamber defining a second processing region and a second transfer region. The first processing chamber and the second processing chamber may be at least substantially aligned along a first vertical axis. Each of the first processing chamber and the second processing chamber may be coupled with at least one transfer chamber. The second processing chamber may include a second substrate support that is vertically translatable between the second processing region and the second transfer region. The second processing chamber may include a second gas delivery assembly disposed above and in alignment with the second substrate support. The systems may include at least one transfer robot disposed within each of the at least one transfer chamber.

In some embodiments, the at least one transfer robot may include a single transfer robot that accesses both the first transfer region and the second transfer region. The systems may include a first load lock that is at least substantially aligned with the first processing chamber along a first horizontal axis. The systems may include a second load lock that is at least substantially aligned with the second processing chamber along a second horizontal axis. The systems may include a factory interface coupled with each of the first load lock and the second load lock. An upper load lock of the first load lock and the second load lock may include an elevator that is coupled with the factory interface. The first processing chamber and the second processing chamber may be operable independently of one another. The systems may include a gas panel. The systems may include one or both of a gas manifold and a gas splitter that control a flow of gas from the gas panel to the first gas delivery assembly and the second gas delivery assembly. The first processing chamber and second processing chamber may share a same gas source, a same vacuum source, a same RF power source, and a same AC power source.

Some embodiments of the present technology may encompass semiconductor processing systems that may include a first processing chamber defining a first processing region and a first transfer region. The systems may include a second processing chamber defining a second processing region and a second transfer region. The first processing chamber and the second processing chamber may be at least substantially aligned along a vertical axis. Each of the first processing chamber and the second processing chamber may be coupled with at least one transfer chamber. The systems may include a first load lock that is at least substantially aligned with the first processing chamber along a first horizontal axis. The systems may include a second load lock that is at least substantially aligned with the second processing chamber along a second horizontal axis. The systems may include a factory interface coupled with each of the first load lock and the second load lock.

In some embodiments, the at least one transfer chamber may include a first transfer chamber that is at least substantially aligned with the first processing chamber along the first horizontal axis and a second transfer chamber that is at least substantially aligned with the second processing chamber along the second horizontal axis. The first transfer chamber and the second transfer chamber may be at least substantially aligned along an additional vertical axis. The first load lock and the second load lock may be aligned along an additional vertical axis. The systems may include a third processing chamber defining a third processing region and a third transfer region. The systems may include a fourth processing chamber defining a fourth processing region and a fourth transfer region. The third processing chamber and the fourth processing chamber may be at least substantially aligned along an additional vertical axis that is offset from and parallel to the vertical axis. Each of the third processing chamber and the fourth processing chamber may be coupled with the at least one transfer chamber. The at least one transfer chamber may include a first transfer chamber that is at least substantially aligned with the first processing chamber and the third processing chamber along the first horizontal axis and a second transfer chamber that is at least substantially aligned with the second processing chamber and the fourth processing chamber along the second horizontal axis. The first processing chamber and the second processing chamber may be positioned on a same side of the at least one transfer chamber as the third processing chamber and the fourth processing chamber.

Such technology may provide numerous benefits over conventional systems and techniques. For example, the processing systems may provide multi-substrate processing capabilities that may be scaled well beyond conventional designs. For example, embodiments may vertically stack multiple chambers atop one another to more effectively use vertical space. The stacked chambers may be operated concurrently and/or independently of one another, which may improve throughput and/or add redundancy in the event of the need to service one of the stacked chambers. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic side elevation cross-sectional view of an exemplary plasma system with vertically stacked chambers according to some embodiments of the present technology.

FIG. 3 shows a schematic side elevation cross-sectional view of an exemplary plasma system with vertically stacked chambers according to some embodiments of the present technology.

FIG. 4 shows a schematic side elevation cross-sectional view of an exemplary plasma system with vertically stacked chambers according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may result in an inefficient use of space as the footprint of the cluster tool scales. Accordingly, the present technology may include cluster tools with an increased number of processing chambers within a defined footprint. To accommodate the limited footprint about transfer robots, the present technology may increase the number of processing chambers vertically and/or laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions. Additionally, the present invention may vertically stack two or more chambers along a common vertical access to make more efficient use of the vertical space within the defined footprint.

However, as additional process locations are added, accessing these locations from a central robot may no longer be feasible without additional transfer capabilities at each location. Some conventional technologies may include wafer carriers on which the substrates remain seated during transition. However, wafer carriers may contribute to thermal non-uniformity and particle contamination on substrates. The present technology overcomes these issues by incorporating two or more processing chamber regions that are vertically stacked atop one another and one or more carousels or transfer apparatuses that may operate in concert with one or more central robots to access the vertically stacked wafer positions. The present technology may not use conventional wafer carriers in some embodiments, and may transfer specific wafers from one substrate support to a different substrate support within the transfer region. In some embodiments, each vertical level of one or more processing regions may be aligned with a central transfer robot that may transfer substrates to one or more processing regions at that vertical level. Thus, multiple transfer robots may be vertically stacked. In some embodiments, a single factory interface robot may be designed with z-motion (e.g., vertical) travel capabilities such that a single factory interface robot may transfer substrates to load locks at different vertical levels, for subsequent access by a given transfer robot.

Although the remaining disclosure will routinely identify specific structures, such as four-position chamber systems, for which the present structures and methods may be employed, it will be readily understood that the systems and methods are equally applicable to any number of structures and devices that may benefit from the structural capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

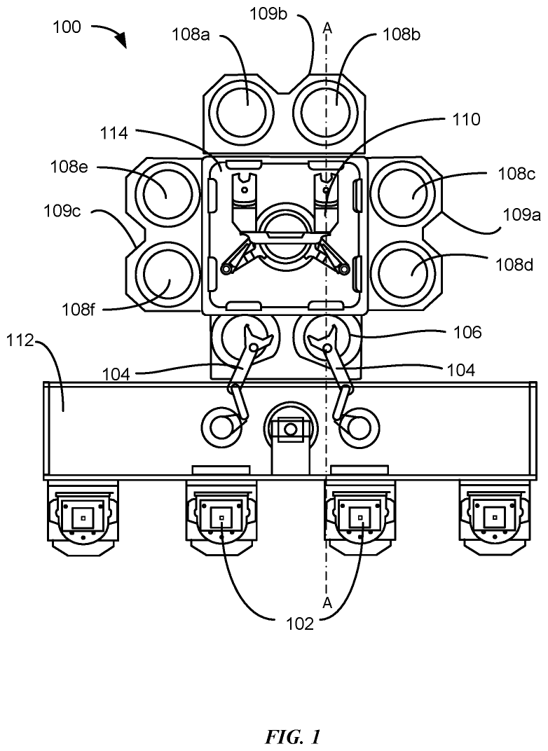

FIG. 1 shows a top plan view of one embodiment of a processing system 100 of deposition, etching, baking, and curing chambers according to embodiments. In the figure, a number of front opening unified pods 102 supply substrates of a variety of sizes that are received by robotic arms 104 of a factory interface 112 and placed into a load lock or other low pressure holding area 106 before being placed into one of the substrate processing chambers 108a-f, positioned in tandem sections 109a-c. While shown with four front opening unified pods 102 positioned along a single side of the factory interface 112, it will be appreciated that any number of front opening unified pods 102 may be included and positioned about one or more sides of the factory interface 112 in various embodiments. For example, the system 100 may include at least or about one front opening unified pod 102, at least or about two front opening unified pods 102, at least or about three front opening unified pods 102, at least or about four front opening unified pods 102, at least or about five front opening unified pods 102, at least or about six front opening unified pods 102, or more. There may be one or more chambers positioned below some or all of the substrate processing chambers 108a-f in some embodiments. This may enable a number of processing chambers 108 to be doubled, tripled, or otherwise multiplied to make better use of the vertical space within a given footprint. One or more transfer chambers 114 may be positioned proximate the holding areas 106. For example, two or more transfer chambers may be stacked vertically relative to one another. In some embodiments, each vertical level of processing chambers 108a-f may have one or more dedicated transfer chambers 114 such that a number of transfer chambers 114 is equal to an integer multiple of the number of levels of processing chambers 108. One or more transfer robots 116 may be positioned in each transfer chamber 114, with each transfer robot 116 including at least one second robotic arm 110 that may include at least one end effector assembly (e.g., one or more linkages and end effectors) that may be used to transport the substrate wafers from the holding area 106 to the substrate processing chambers 108 and back. In some embodiments, a single processing chamber 114 may have z-motion (e.g., vertical movement) capabilities and may be used to transfer substrates to and from processing chambers 108 on different vertical levels. Each substrate processing chamber 108, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108 may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

As illustrated, the processing chambers 108 are arranged in side-by-side pairs, with each pair of processing chambers 108 being positioned about a different side of the transfer chamber 114. In the present embodiment, the transfer chamber 114 (or chambers, where multiple transfer chambers are vertically stacked atop one another), includes four sides, three of which are coupled with the processing chambers 108. A fourth side of the transfer chamber 114 may be coupled with two or more holding areas 106, which may be positioned side-by-side in some embodiments. The factory interface 112 may be coupled with each of the holding areas 106, and in some embodiments may be positioned on an opposite side of each holding area 106 as the transfer chamber 114. The front opening unified pods 102 (here, four) may be coupled with the factory interface 112, such as positioned along a single side of the factory interface 112 opposite the holding areas 106. In other embodiments, one or more of the front opening unified pods 102 may be positioned on different sides of the factory interface 112.

It will be appreciated that the layout of system 100 is merely provided as an example and that numerous variations may exist in different embodiments. For example, system 100 may include more or fewer numbers of processing chambers 108 positioned about one or more sides of the transfer chamber. The processing chambers 108 may be positioned as single units, pairs, triplets, and/or any other number of processing chambers 108 about one or more sides of the transfer chamber 114, which may include any number of sides in various embodiments. Additionally, more or fewer holding areas 106 may be provided on one or more sides of the transfer chamber 114, and more or fewer front opening unified pods 102 may be coupled with one or more sides of the factory interface 112. Additionally, while shown with two robotic arms in each of the transfer chamber 114 and the factory interface 112, it will be appreciated that some embodiments may include more or fewer robotic arms in one or both areas.

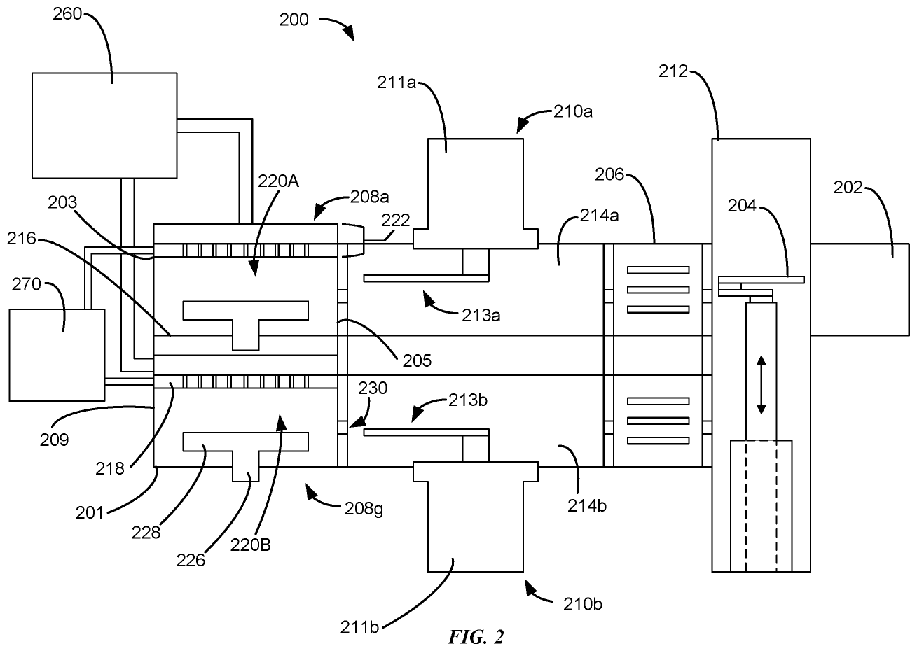

FIG. 2 shows a schematic cross-sectional view of an exemplary processing system 200 according to some embodiments of the present technology. For example, the processing system 200 may illustrate a cross-section of FIG. 1 taken along line A-A in some embodiments. Processing system 200 may illustrate a pair of vertically stacked processing chambers 208a, 208g that may be fitted in the horizontal footprint of a single one of the processing chambers 108 described above, and which may include substrate support assemblies according to embodiments of the present technology. The processing chambers 208a, 208g may be at least substantially aligned along a vertical axis (e.g., within 10 inches, within 5 inches, within 3 inches, within 1 inch, or less). Each processing chamber 208 may include a chamber body 201 having sidewalls 209, a bottom wall 216, and an interior sidewall 205 defining a pair of processing regions 220A and 220B. In some embodiments, the processing chambers 208 may share one or more walls, such as sidewall 209, although in other embodiments each processing chamber 208 may include its own distinct chamber body 201 and walls 209. Each of the processing regions 220A-220B may be similarly configured, and may include identical components in some embodiments. In other embodiments, the processing regions 220A-220B may be differently configured and may include one or more different components. The processing regions 220A-220B may be fluidly isolated from one another in some embodiments. This may enable the processing regions to operate independently of one another, which may enable the processing regions to perform the same and/or different processing operations in synch with one another, or at different times. Such independent operation of the chambers 208 may improve the redundancy of the processing system 200, as a single chamber 208 may be taken out of operation (such as for servicing) while the remaining chambers 208 may continue processing substrates.

For example, processing region 220B, the components of which may also be included in processing region 220A, may include a pedestal 228 disposed in the processing region through a passage formed in the bottom wall 216 in the processing chamber 208. The pedestal 228 may provide a heater adapted to support a substrate on an exposed surface of the pedestal, such as a body portion. The pedestal 228 may include embedded heating elements, for example resistive heating elements, which may heat and control the substrate temperature at a desired process temperature. Pedestal 228 may also be heated by a remote heating element, such as a lamp assembly, or any other heating device.

The body of pedestal 228 may be coupled with a stem 226. The stem 226 may electrically couple the pedestal 228 with a power outlet or power box. The power box may include a drive system that controls the elevation and movement of the pedestal 228 within the processing region 220B. For example, each pedestal 228 may be translated between a transfer region in which substrates may be exchanged between the processing chamber 208 and a transfer robot 210 and a processing region that is disposed above the transfer region and in which one or more substrate processing operations may be performed. In some embodiments, the pedestals 228 of processing chambers 208a, 208g may share a power box (or other power source), filter, heater, and/or a drive system. In other embodiments, each pedestal 228 may include a dedicated power box and/or drive system. The pedestals 228 may be operated (e.g., heated, translated, powered, etc.) together (e.g., synchronized) and/or independently of one another.

A chamber lid 203 may be coupled with a top portion of the chamber body 201. The lid 203 may accommodate one or more gas delivery or gas delivery assemblies 222 coupled thereto, such as one gas delivery assembly 222 per processing chamber 208. Each gas delivery assembly 222 may include one or more precursor inlet passages which may deliver reactant and cleaning precursors through one or more components of the gas delivery assembly 222 into the respective processing region 220. The gas delivery assembly 222 may include various components that may help uniformly distribute one or more precursors, plasmas, cleaning gases, and/or other gases into the processing region 220. For example, the gas delivery assembly 222 may include one or more gas boxes, one or more manifolds, one or more blocker plates, one or more showerheads 218, and/or other gas distribution components. The gas delivery assembly 222 may be disposed above and in alignment with a respective one of the substrate supports or pedestals 228. For example, central axes of the pedestal 228 and the gas delivery assembly 222 may be coaxial with one another.

In some embodiments, a radio frequency (“RF”) source may be coupled with one or more components of the gas delivery assembly 222, such as a showerhead 218, which may power the components to facilitate generating a plasma region between the component and the pedestal 228. In some embodiments, the RF source may be coupled with other portions of the chamber body 201, such as the pedestal 228, to facilitate plasma generation. In such embodiments, a dielectric isolator may be disposed between the lid 203 and the showerhead 218 (or other RF powered component of the gas delivery assembly 222) to prevent conducting RF power to the lid 203.

Each gas delivery system 222 may be coupled with a gas panel 260 and/or other gas source. In some embodiments, each gas delivery assembly 222 may include a dedicated gas panel 260, while in other embodiments two or more (or all) gas delivery assemblies 222 may be coupled with a single gas panel 260. In such embodiments, one or more gases may be flowed from the gas panel 260 to one or more gas manifolds and/or gas splitters that may distribute and control the flow of gases to each processing chamber 208. In some embodiments a remote plasma source (RPS) 270 may be coupled with each of the chambers 208. For example, the RPS 270 may be positioned on the lid 203 and/or along one of the sidewalls of the chambers 208. In some embodiments a single RPS 270 may be fluidly coupled with one or more (or all) chambers 208 in the system 200 via one or more valves, weldments, manifolds, and/or other fluid paths. For example, the showerhead 218 may be a dual channel showerhead that enables gases from the gas delivery assembly 222 to be flowed into a given chamber 208 through a first channel, while plasma and/or inert gases may be flowed to the chamber 208 from the RPS via a second channel of the showerhead 218. In some embodiments, each of the upper and lower processing chambers 208 may share a same gas source, a same vacuum source, a same RF power source, and/or a same AC/DC power source, while in other embodiments, one or more of the processing chambers 208 may have a different gas source, vacuum source, RF power source, and/or AC/DC power source.

Each processing region 220 of the system 200 may be coupled with a transfer chamber 214. For example, the chamber body 201 may define and/or otherwise include one or more slit valves 230 that couple a processing region 220 with a respective transfer chamber 214. Each slit valve 230 may enable substrates to be transferred in and out of the processing regions 220 when open and may provide an airtight seal to enable careful control of pressure within each processing region 220 during processing operations. As illustrated, each vertical level of processing regions 220 has its own transfer chamber 214 (with the transfer chambers being at least substantially aligned along a vertical axis), however in some embodiments two or more vertical levels of processing regions may share a single transfer chamber 214. Each transfer chamber 214 may include a transfer robot 210 that may transfer substrates between the processing regions 220 and attached holding areas 206 (such as load locks), which may maintain the substrates at a low pressure. Each transfer robot 210 may be similar to transfer robot 110 and may include a motor assembly 211 that may include processors, motors (or other actuators), transmission members, and/or other internal components of the transfer robot 210 which may extend beyond the vertical space of the transfer region 214. Various system designs may be implemented to accommodate the extra equipment of the transfer robots 210. In the illustrated embodiment, the motor assemblies 211 of each transfer robot 210 are inverted and positioned opposite one another. For example, a motor assembly 211 of the upper transfer robot 210a may be positioned above an end effector assembly 213a of the upper transfer robot 210a, such as on an outer-facing side of the upper transfer chamber 214a. The motor assembly 211 of the lower transfer robot 210b may be positioned below an end effector assembly 213b of the lower transfer robot 210b, such as on an outer-facing side of the lower transfer chamber 214b. Such a positioning may enable the space between the upper and lower transfer chambers 214 (and effectively the upper and lower processing chambers/regions) to be reduced. The end effector assemblies 213 of each transfer robot 210 may be oriented in a same direction, which may enable the end effector assemblies 213 to transfer substrates with the substrates face up, and deposit the substrates face up on a respective pedestal 228. By inverting the motor assemblies 211 and positioning the motor assemblies 211 on opposing sides of the respective transfer chambers 214, the vertical space between vertically adjacent processing regions may be reduced. For example, the distance between vertically adjacent processing regions may be between about 500 and 1500 mm, between about 600 mm and 1400 mm, between about 700 mm and 1300 mm, between about 800 mm and 1200 mm, or between about 900 mm and 1100 mm. Additionally, such designs move the motor assemblies 211 out of the interior of the transfer chambers 214 and may enable the motor assemblies 211 to be more easily serviced. For example, some or all of the motor assemblies 211 may include one or more lids and/or hatches that may facilitate easy access to the internal components of the motor assembly 211 without the need to access the interior of the transfer chamber 214 itself.

Each transfer chamber 214 may be coupled with one or more holding areas 206, which may serve to store substrates that are to be processed. For example, substrates may be transported to the holding areas 206, such as by a factory interface robot, which may be maintained in a higher-pressure environment than the transfer chambers 214 and/or processing chambers 208 (e.g., the factory interface robot may be present in an atmospheric pressure environment). Once one or more substrates have be loaded into the holding area 206, the holding area 206 may be pumped down to a vacuum pressure environment prior to exposing the substrates to the transfer chamber environment. The use of holding areas 206 may help increase the throughput of the system 200. As illustrated, each vertical level of the system 200 includes a separate set of one or more holding areas 206, which may be vertically aligned with a respective one of the transfer chambers 214 and processing chambers 208 to enable one of the transfer robots 210 to grasp and/or otherwise maneuver substrates between the holding area 206 and the transfer chamber 214 and/or the respective processing chamber 208. For example, a lower holding area 206b may be vertically aligned with the lower transfer chamber 214b and the lower processing chamber 208g along a first horizontal axis, while an upper holding area 206a may be vertically aligned with the upper transfer chamber 214a and the upper processing chamber 208a along a second horizontal axis. The upper and lower holding areas 206 may be vertically stacked atop one another such that the holding areas 206 are aligned or substantially aligned along a vertical axis. In some embodiments, one or more of the holding areas 206 may include an elevator and/or other mechanism that helps lift substrates from the factory interface 112 robotic arms 204 to a height of the transfer robot 210. For example, the upper holding area 206 may include an elevator, which may reduce the amount of z-direction travel of the robotic arms 204 and may increase the throughput and efficiency of the system 200.

The system 200 may include a factory interface 212 that may include one or more robotic arms 204. The robotic arms 204 may operate to transfer substrates between one or more front opening unified pods 202 and the holding areas 206. In some embodiments, the robotic arms 204 and/or other portion of factory interface 212 may be vertically translatable (e.g., in a z-direction). Such translation may enable a single factory interface 212 and/or set of one or more robotic arms 204 to transfer substrates to holding areas 206 on different vertical levels (e.g., both the upper and lower holding areas). For example, the robotic arms 204 may be positioned on a shaft or other support that is coupled with a linear actuator that translates the robotic arms 204 to various heights, such as the heights of the different holding areas 206, transfer chambers 214, and processing chambers 208.

In some embodiments, each stacked chamber and/or processing region may be centered within a same footprint, which may enable the transfer robots, processing chambers, transfer chambers, and/or other components to all have a same or similar size and design, which may simplify manufacturing and assembly of the chambers, as well as improve processing uniformity from one stacked chamber to another. While shown with two chambers stacked vertically, it will be appreciated that any number of chambers may be stacked in various embodiments.

As noted above with respect to FIG. 1, any number of processing chambers 208 may be provided on a given vertical level. As just one example, the processing system 200 may include a third processing chamber (e.g., processing chamber 108b) defining a third processing region and a third transfer region and a fourth processing chamber (e.g., a processing chamber below processing chamber 108b and positioned alongside processing chamber 208g) defining a fourth processing region and a fourth transfer region. In such embodiments, the third processing chamber and the fourth processing chamber may be at least substantially aligned along an additional vertical axis that is offset from and parallel to the vertical axis about which the upper and lower processing chambers 208 are aligned. For example, the upper and lower processing chambers 208 may be aligned about a vertical axis that passes through a center of a chamber positioned similarly as chamber 108a, while the third and fourth processing chambers may be aligned about a vertical axis that passes through a center of a chamber positioned similarly as chamber 108b. The third and fourth processing chambers may be coupled with at least one transfer chamber 214. For example, the third processing chamber may be coupled with the upper transfer chamber 214a and the fourth processing chamber may be coupled with the lower transfer chamber 214b. The upper transfer chamber 214a may be aligned with the upper processing chamber 208a and the third processing chamber along a first horizontal axis, while the lower transfer chamber 214b may be aligned with the lower processing chamber 208b and the fourth processing chamber along a second horizontal axis that is below and parallel to the first horizontal axis. While described with the upper, lower, third, and fourth processing chambers being positioned on a same side of the transfer chambers, it will be appreciated that other configurations are possible in various embodiments.

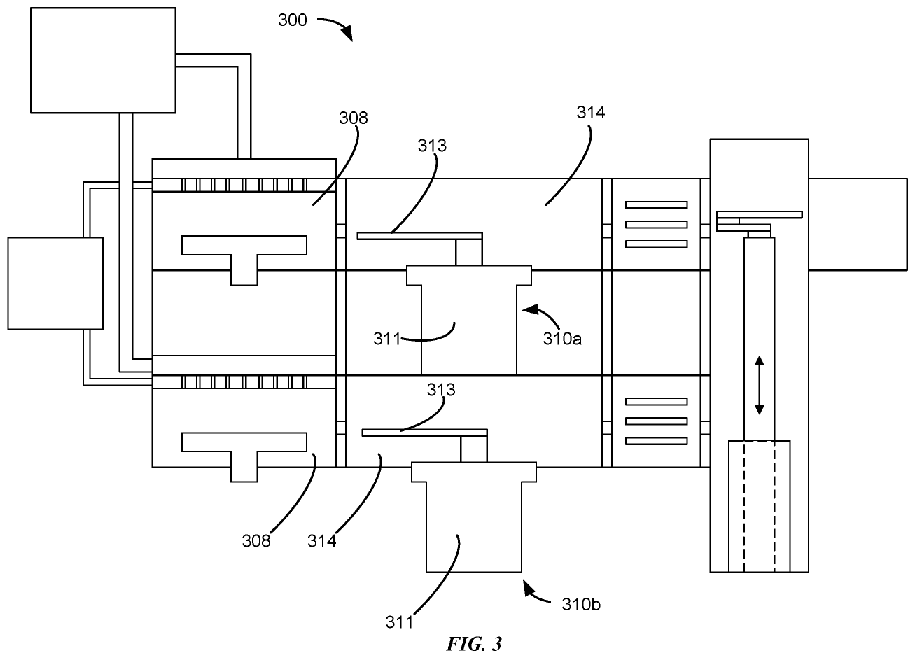

FIG. 3 shows a schematic partial cross-sectional view of an exemplary semiconductor processing system 300 according to some embodiments of the present technology. FIG. 3 may include one or more components discussed above with regard to FIGS. 1 and 2, and may illustrate further details relating to that system. The system 300 may be used to perform semiconductor processing operations including deposition of stacks of dielectric materials as previously described. System 300 may show a partial view of a number of processing chambers of a semiconductor processing system, and may not include all of the components, such as additional lid stack components previously described, which are understood to be incorporated in some embodiments of system 300.

Processing system 300 may be the same as processing system 200 except for the structure of the transfer chambers 314. For example, rather than having motor assemblies 311 of transfer robots 310a and 310b inverted and positioned on opposite sides of their respective transfer chambers 314 as described in relation to FIG. 2, the motor assemblies 311 of the upper and lower transfer robots 310 may be oriented in a same direction, with each motor assembly 311 being positioned on a lower end of (e.g., below) a respective one of the transfer chambers 314. In such embodiments, the end effector assemblies 313 of each transfer robot 310 may be oriented in a same direction (e.g., upward). Such a design may increase the vertical space between vertically adjacent chamber 308, but would enable the same design of transfer robot 310 to be utilized in each processing chamber 308, which may simplify the design and fabrication of the chambers 308 and associated components. While shown with the motor assemblies 311 being positioned on a lower end of (e.g., below) a respective one of the transfer chambers 314, in some embodiments the motor assemblies 311 may each be positioned on an upper end of a respective one of the transfer chambers 314.

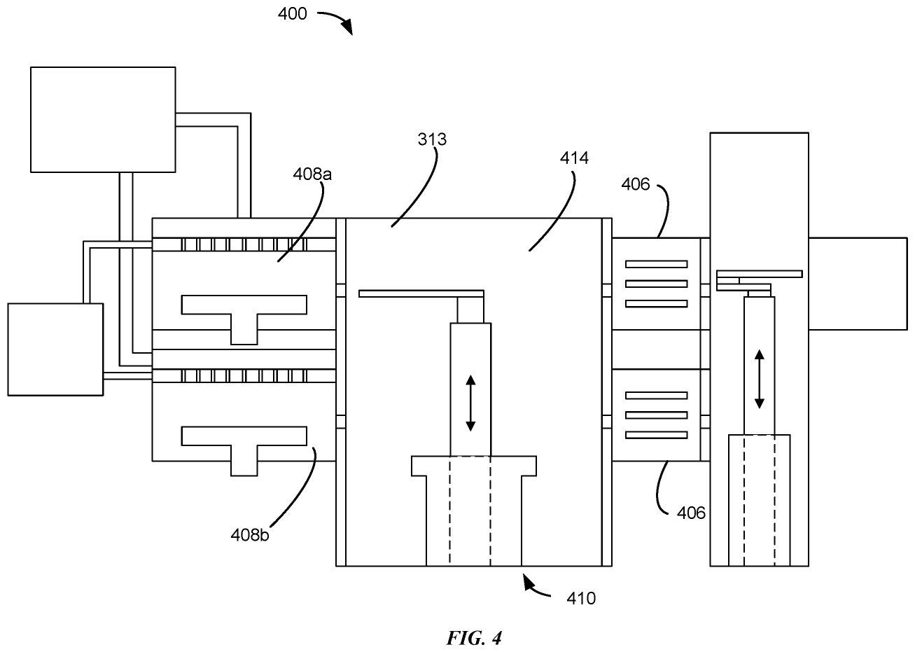

FIG. 4 shows a schematic partial cross-sectional view of an exemplary semiconductor processing system 400 according to some embodiments of the present technology. FIG. 4 may include one or more components discussed above with regard to FIGS. 1-3, and may illustrate further details relating to that system. The system 400 may be used to perform semiconductor processing operations including deposition of stacks of dielectric materials as previously described. System 300 may show a partial view of a number of processing chambers of a semiconductor processing system, and may not include all of the components, such as additional lid stack components previously described, which are understood to be incorporated in some embodiments of system 400.

Processing system 400 may be the same as processing system 200 and/or 300 except for the structure of the transfer chamber 414. For example, rather than having separate transfer chambers 414 and transfer robot 410 for each vertical level of processing chambers 408, system 400 may include a single transfer chamber 414 that is operable to transfer substrates between processing chambers 408 and holding areas 406 at different vertical positions. For example, the transfer chamber 414 may extend from a lowest processing chamber 408b to a highest processing chamber 408a. As illustrated, the transfer chamber 414 may include one or more transfer robots 410, with one or more of the transfer robots 410 being vertically translatable within the transfer chamber 414 such that the transfer robot 410 may access the transfer region of upper and lower processing chambers 408, as well as access the upper and lower holding areas 406. One or more linear actuators may be used to control the vertical translation of the transfer robot 410 to a given height.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the mesh” includes reference to one or more meshes and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a first processing chamber defining a first processing region and a first transfer region having a first slit valve, the first processing chamber comprising:
a first substrate support that is vertically translatable between the first processing region and the first transfer region; and
a first gas delivery assembly disposed above and in alignment with the first substrate support;
a first transfer chamber coupled with the first processing chamber via the first slit valve;
a first transfer robot disposed within the first transfer chamber;
a second processing chamber defining a second processing region and a second transfer region having a second slit valve, wherein the first processing chamber and the second processing chamber are at least substantially aligned along a first vertical axis, the second processing chamber comprising:
a second substrate support that is vertically translatable between the second processing region and the second transfer region; and
a second gas delivery assembly disposed above and in alignment with the second substrate support;
a second transfer chamber coupled with the second processing chamber via the second slit valve; and
a second transfer robot disposed within the second transfer chamber, wherein the first transfer chamber and the second transfer chamber are at least substantially aligned along a second vertical axis.

2. The semiconductor processing system of claim 1, wherein:
the first transfer robot comprises a first motor assembly and a first end effector assembly;
the second transfer robot comprises a second motor assembly and a second end effector assembly;
the first motor assembly and the second motor assembly are inverted relative to one another and are each positioned on an outer-facing side of a respective one of the first transfer chamber and the second transfer chamber; and
the first end effector assembly and the second end effector assembly are oriented in a same direction.

3. The semiconductor processing system of claim 1, wherein:
the first transfer robot comprises a first motor assembly and a first end effector assembly;
the second transfer robot comprises a second motor assembly and a second end effector assembly;
the first motor assembly and the second motor assembly are oriented in a same direction, and are each positioned on a lower end of a respective one of the first transfer chamber and the second transfer chamber; and
the first end effector assembly and the second end effector assembly are oriented in a same direction.

4. The semiconductor processing system of claim 1, wherein:
the first substrate support and the second substrate support are operable both independently and concurrently with one another.

5. The semiconductor processing system of claim 1, wherein:
the first transfer chamber and the second transfer chamber are fluidly isolated from one another.

6. The semiconductor processing system of claim 1, further comprising:
a first load lock that is at least substantially aligned with the first processing chamber along a first horizontal axis; and
a second load lock that is at least substantially aligned with the second processing chamber along a second horizontal axis.

7. The semiconductor processing system of claim 6, further comprising:
a factory interface coupled with each of the first load lock and the second load lock.

8. A semiconductor processing system, comprising:
a first processing chamber defining a first processing region and a first transfer region, the first processing chamber comprising:
a first substrate support that is vertically translatable between the first processing region and the first transfer region; and
a first gas delivery assembly disposed above and in alignment with the first substrate support;
a second processing chamber defining a second processing region and a second transfer region, wherein:
the first processing chamber and the second processing chamber are at least substantially aligned along a first vertical axis;
each of the first processing chamber and the second processing chamber are coupled with at least one transfer chamber; and
the second processing chamber comprises:
a second substrate support that is vertically translatable between the second processing region and the second transfer region; and
a second gas delivery assembly disposed above and in alignment with the second substrate support; and
at least one transfer robot disposed within each of the at least one transfer chamber.

9. The semiconductor processing system of claim 8, wherein:
the at least one transfer robot comprises a single transfer robot that accesses both the first transfer region and the second transfer region.

10. The semiconductor processing system of claim 8, further comprising:
a first load lock that is at least substantially aligned with the first processing chamber along a first horizontal axis;
a second load lock that is at least substantially aligned with the second processing chamber along a second horizontal axis; and
a factory interface coupled with each of the first load lock and the second load lock.

11. The semiconductor processing system of claim 10, wherein:
an upper load lock of the first load lock and the second load lock comprises an elevator that is coupled with the factory interface.

12. The semiconductor processing system of claim 8, wherein:
the first processing chamber and the second processing chamber are operable independently of one another.

13. The semiconductor processing system of claim 8, further comprising:
a gas panel; and
one or both of a gas manifold and a gas splitter that control a flow of gas from the gas panel to the first gas delivery assembly and the second gas delivery assembly.

14. The semiconductor processing system of claim 8, wherein:
the first processing chamber and second processing chamber share a same gas source, a same vacuum source, a same RF power source, and a same AC power source.

15. A semiconductor processing system, comprising:
a first processing chamber defining a first processing region and a first transfer region;
a second processing chamber defining a second processing region and a second transfer region, wherein:
the first processing chamber and the second processing chamber are at least substantially aligned along a vertical axis; and
each of the first processing chamber and the second processing chamber are coupled with at least one transfer chamber;
a first load lock that is at least substantially aligned with the first processing chamber along a first horizontal axis;
a second load lock that is at least substantially aligned with the second processing chamber along a second horizontal axis; and
a factory interface coupled with each of the first load lock and the second load lock.

16. The semiconductor processing system of claim 15, wherein:
the at least one transfer chamber comprises a first transfer chamber that is at least substantially aligned with the first processing chamber along the first horizontal axis and a second transfer chamber that is at least substantially aligned with the second processing chamber along the second horizontal axis; and
the first transfer chamber and the second transfer chamber are at least substantially aligned along an additional vertical axis.

17. The semiconductor processing system of claim 15, wherein:
the first load lock and the second load lock are aligned along an additional vertical axis.

18. The semiconductor processing system of claim 15, further comprising:
a third processing chamber defining a third processing region and a third transfer region;
a fourth processing chamber defining a fourth processing region and a fourth transfer region, wherein:
the third processing chamber and the fourth processing chamber are at least substantially aligned along an additional vertical axis that is offset from and parallel to the vertical axis; and
each of the third processing chamber and the fourth processing chamber are coupled with the at least one transfer chamber.

19. The semiconductor processing system of claim 18, wherein:
the at least one transfer chamber comprises a first transfer chamber that is at least substantially aligned with the first processing chamber and the third processing chamber along the first horizontal axis and a second transfer chamber that is at least substantially aligned with the second processing chamber and the fourth processing chamber along the second horizontal axis.

20. The semiconductor processing system of claim 18, wherein:
the first processing chamber and the second processing chamber are positioned on a same side of the at least one transfer chamber as the third processing chamber and the fourth processing chamber.
